(19) United States
(12) Patent Application Publication
(10) Pub. No.: US 2011/0059230 A1
(43) Pub. Date: Mar. 10, 2011

(54) METHOD FOR METALIZING SOLAR CELLS, HOT-MELT AEROSOL INK, AND AEROSOL JET PRINTING SYSTEM

(75) Inventors: Matthias Hoerteis, Freiburg (DE); Philipp Richter, Freiburg (DE); Stefan Glunz, Freiburg (DE)

(73) Assignee: FRAUNHOFER-GESELLSHAFT ZUR FOERDERUNG DER ANGEWANDTEN FORSCHUNG E.V., Munich (DE)

(21) Appl. No.: 12/734,952

(22) PCT Filed: Oct. 13, 2008
(86) PCT No.: PCT/EP2008/008648

§ 371 Date: Nov. 15, 2010

(30) Foreign Application Priority Data
Dec. 7, 2007 (DE) 10 2007 058 972.9

(51) Int. Cl. H01B 1/22; B05D 5/12; C23C 16/00

(52) U.S. Cl. 427/74; 118/716; 252/514; 252/513; 252/515; 252/512

(57) ABSTRACT

The present invention relates to a novel method for applying conductive structures on solar cells, a hot melt aerosol ink being atomised by means of an aerosol jet printing system and being discharged from the printing system in the direction of the solar cell, the printing system being heated at least partially in order to keep low the viscosity of the ink which is used. When impinging on the non-heated substrate (solar cell), the ink solidifies.

The present invention relates to a novel method for applying conductive structures on solar cells, a hot melt aerosol ink being atomised by means of an aerosol jet printing system and being discharged from the printing system in the direction of the solar cell, the printing system being heated at least partially in order to keep low the viscosity of the ink which is used. When impinging on the non-heated substrate (solar cell), the ink solidifies.

For conductive contacts on solar cells, in particular in the case of front-side contacts, it is desirable to keep the contact surface as small as possible and at the same time maintain the electrical conductivity of the contact grid high. A small contact surface prevents too great shading and reduces the recombination of charge carriers. Good conductivity of the contact grid reduces the electrical losses. Both can be achieved in that a printed contact is formed to be as narrow as possible and at the same time as high as possible. The ratio of height to width is termed aspect ratio.

Solar cells are metallised predominantly by means of screen printing. A metal paste is thereby pressed through a screen so that, corresponding to the opening in the screen, the metal paste is transferred onto the substrate. Line widths of 60 μm to 120 μm are thereby achieved and have a height of 10 to 20 μm. The line widths are thereby approx. 5 μm to 15 μm wider than the opening in the screen. Slight running of the paste is accepted. Screen printing pastes use particle sizes between d=1 μm and 10 μm.

In order almost completely to prevent running hot melt pastes can be used. These concern screen printing pastes which become high-viscous at room temperature and low-viscous at higher temperatures of 40° C. to 90° C. This is achieved in that the solvent of the pastes is replaced by a thermoplastic polymer system. Hot melt pastes are used for the metallisation during screen printing and tampon printing.

A further possibility of achieving a good aspect ratio resides in constructing the contact in two steps. In a first step, a very narrow and also flat metal layer (seed layer) is printed and is reinforced galvanically in a second step. In order to achieve a good aspect ratio of the galvanically reinforced contact, it is necessary to print the seed layer to be very narrow. The narrower the seed layer, the better can the aspect ratio become. With the existing aerosol jet technique, line widths of below 20 μm can be achieved. However these merely have a height of at most 2 μm. Aerosol jet inks are distinguished by low viscosity so that they can be atomised easily. Aerosol inks include a solvent with a low vapour pressure and viscosity. The viscosity of the inks at room temperature is typically below η=1 Pas.

When printing metal contacts on substrates, such as e.g. silicon solar cells or glass, the result, because of the viscosity of the ink, is spreading and hence widening of the printed line. This is particularly significant in contact-free printing methods, such as ink jet or aerosol jet techniques, but also in contact methods, such as tampon printing or screen printing. Running of the lines effects furthermore a small application height and hence an unfavourable aspect ratio.

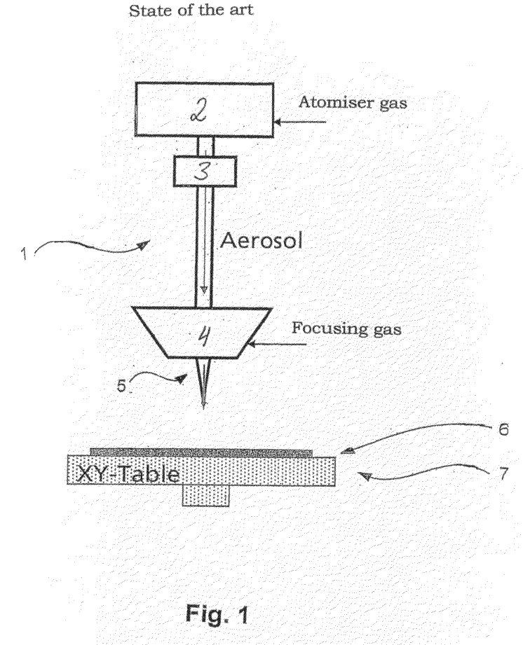

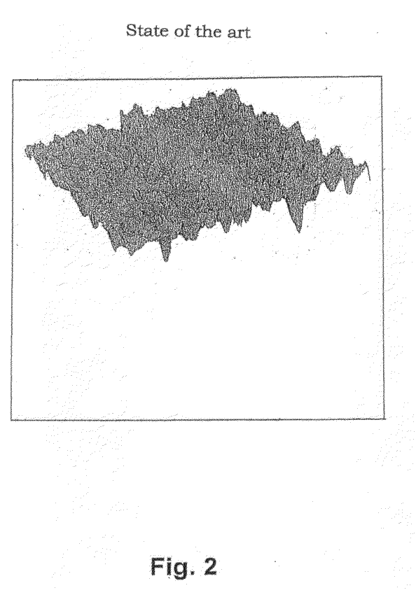

The aerosol jet technique is an ink jet method with which it is possible to print flat and thin lines. The technique is used in order to produce thin metal contacts (contact width 20 μm to 60 μm, contact height <2 μm) in a single printing pass. These thin metal contacts serve as seed layer for the galvanic reinforcing. These contact widths (20 μm to 60 μm) can however be achieved only if the substrate is heated to far above room temperature (FIGS. 1 and 2). The heating has the effect that the solvent in the aerosol evaporates after impinging on the substrate, the ink dries and can no longer run on the substrate. Temperatures of 100° C. to 200° C. are required for this purpose. To date, this high substrate temperature has made difficult or prevented industrial use of the printing method since the cycle times are lower than in the case of printing at room temperature. Furthermore, an increased safety risk is always present with the combination of solvent and high temperatures.

Starting herefrom, it was the object of the present invention to provide an optimised method for the production of conductive structures on solar cells, which method enables automated and reproducible application of metallisations on solar cells. In particular, an advantageous aspect ratio of the applied contact is thereby intended to be made possible.

This object is achieved with the method according to the invention according to patent claim 1. A hot melt aerosol ink is provided by patent claim 18, which has advantageous properties in the metallisation process. In patent claim 27, an aerosol jet printing system according to the invention for the metallisation of solar cells is indicated.

The method according to the invention hence relates to a method for applying conductive structures on solar cells, in which a conductive contact is applied by means of an aerosol jet printing system on the substrate surface of the solar cell, a hot melt aerosol ink being atomised and the aerosol jet printing system being heated at least partially, with the proviso that the hot melt aerosol ink used has a viscosity η≦1 Pas at a temperature of at least 40° C.

In the case of the method according to the invention, a hot melt aerosol ink is hence atomised in the aerosol jet printing system at increased temperatures so that the ink has a defined, advantageous viscosity which enables favourable atomisation of the ink. According to the invention, the viscosity must be at least ≦1 Pas at 40° C. In the following, the thus atomised ink is discharged from the aerosol jet printing system in the direction of the solar cell (substrate). Upon impinging on the substrate, the ink is abruptly cooled and solidifies there.

The consequently formed metal contact is now distinguished by an excellent aspect ratio (height to width) of 1:3 to 1:10, preferably of 1:3 to 1:5.

For the method it is thereby important that the hot melt aerosol ink which is used is chosen by adjusting the composition and viscosity thereof such that the viscosity indicated in claim 1 of η≦1 Pas at at least 40° C. can be achieved.

The hot melt aerosol ink used thereby contains 50 to 90% by weight of conductive particles as solids which are dispersed in a thermoplastic compound. In order to be able to form defined contacts, it is preferred if the conductive particles used have a diameter d₉₀ of less than 500 nm. Furthermore, the ink can contain further solids, such as in particular metal oxides and/or glass frits.

The thermoplastic compound of the ink in which the solids are dispersed is in particular one or more C₁₄ to C₂₀ alcohols and/or thermoplastic polymers. C₁₄-C₁₆ alcohols are preferred.

The ink which is used preferably in the method is defined in particular by the following formulation:

a) 50 to 90% by weight of solids, comprising metal particles, metal oxides and/or glass frits,

b) 10 to 20% by weight of a C₁₄ to C₂₀ linear alcohol as thermoplastic compound,

c) 10 to 30% by weight of a solvent and

d) 0.01 to 1% by weight of additives, the sum of the individual formulation components a) to d) being 100% by weight.

As already explained, it is important for the method that the ink used is formulated such that a problem-free atomisation at increased temperature in the system is possible.

It was able to be shown that the ink must have a viscosity q of 200 Pas at room temperature in order to avoid running on the substrate. Favourable viscosity at room temperature is between 200 and 5,000 Pas, particularly preferred between 200 and 500 Pas.

The system to be used thereby comprises at least one atomiser, one concentrator (virtual impactor) and one printing head, as are known from the state of the art. According to the invention, it is now provided to heat partially at least one of these components of the aerosol jet printing system in order to obtain the desired property. The atomiser can hereby be operated with an atomiser gas which is heated to 70 to 100° C.

The ink within the printing system should be kept at a temperature of 40 to 70° C. It is favourable for this purpose if the concentrator (virtual impactor), the printing head and also the transport hoses connecting the individual components are kept at a temperature of 50 to 100° C.

It has emerged as particularly advantageous if the aerosol jet printing system used is configured to be completely heatable.

With the method, it is hence possible to apply conductive contacts, in particular metallisations, on solar cells. Because of the particularly advantageous aspect ratio of the applied metallisations, the method is suitable preferably for applying front-side contacts on solar cells.

The substrate surface is thereby formed in particular from silicon or glass in coated or uncoated state, e.g. with SiO₂, SiN_{X}, TCO, α-Si, TiO₂.

The preferred aspect ratio is thereby 1:3 to 1:10, preferably 1:3 to 1:5.

Furthermore, it is advantageous in the present method that the substrate surface of the solar cell need not be heated or cooled. It is hereby essential that the temperature of the substrate surface is such that solidification of the ink used upon impinging on the substrate is effected in the shortest possible time.

Subsequent to the above-described type of production of the metallisation, a galvanic thickening or reinforcing, preferably by galvanising with silver and/or copper, is implemented, as known from the state of the art, in order to strengthen or reinforce and/or increase the conductivity of the applied metallisation structure.

Furthermore, the invention relates to a hot melt aerosol ink, as described above.

Specific control of the viscosity is effected in particular by the quantity and type of thermoplastic polymer used. The viscosity η thereby is RT≧200 Pas, preferably it is in the range of 200 to 5,000 Pas, particularly preferred in the range of 200 to 500 Pas.

The metal particles which are used are selected in particular from the group comprising silver, nickel, tin, zinc, chromium, cobalt, tungsten, titanium and/or mixtures thereof.

Furthermore, it is preferred if in particular the metal oxides lead oxide, bismuth oxide, titanium oxide, aluminium oxide, magnesium oxide and/or mixtures thereof are contained in the ink.

In particular, the thermoplastic compounds are thereby selected from the group comprising C₁₆ to C₂₀, preferably C₁₄-C₁₆ linear aliphatic alcohols and/or multivalent alcohols, such as hexane-1,6-diol.

The solvent contained in the ink is preferably selected from glycol ether, M-methylpyrrolidone, 2-(2-butoxyethoxy)ethanol and/or mixtures thereof.

Furthermore, it is preferred if the hot melt aerosol ink contains as additive dispersants and/or defoamers.

According to the invention, an aerosol jet printing system comprising at least one atomiser, one concentrator and one printing head and also connection hoses connecting these components is likewise provided, the printing system according to the invention being distinguished in that at least one of the previously mentioned components is configured to be heatable, it is preferred if all the components are configured to be heatable.

The present invention is described in more detail with reference to the subsequent description, given by way of example, and also the accompanying Figures without restricting the description to the special embodiments mentioned there.

An example of a hot melt aerosol ink according to the invention:

composition in percent by weight (% by weight): solids proportion (metal powder, metal oxides, glass frit) 70.5% by weight, long-chain alcohol C₁₄+10.5% by weight of solvents with low vapour pressure (glycol ether) 19% by weight, dispersants 0.5% by weight.

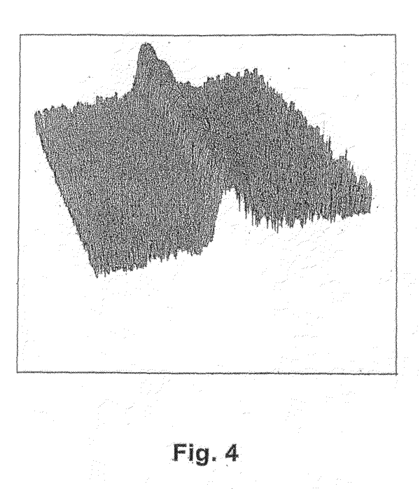

With the above-described hot melt aerosol ink, an aerosol jet printing system which is illustrated schematically as in FIG. 4 was operated.

There are shown

FIG. 1 a conventional aerosol jet printing system in which a heated substrate is used,

FIG. 2 the result of a conventional aerosol jet print known from the state of the art,

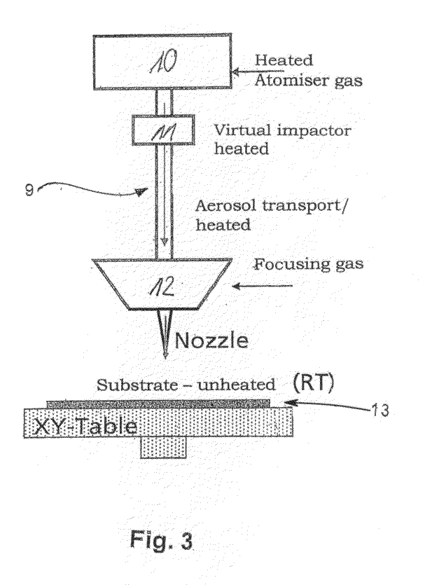

FIG. 3 the schematic representation of an aerosol jet printing system according to the invention,

FIG. 4 the result of the aerosol jet printing method according to the invention, and

FIG. 1 shows an aerosol jet printing device 1 from the state of the art, the atomiser 2 being operated with an atomiser gas. The aerosol produced in the virtual impactor 3 is discharged in the direction of the heated substrate 6 via the printing head 4, to which in addition a focusing gas is added, via a nozzle 5. An xy table is thereby designated with 7. With this method, only inadequate results can however be achieved. The temperature of the substrate 6 is normally 150° C.

By means of the heated substrate, only a low application height (FIG. 2) of approx. 2 μm can be achieved and a poor aspect ratio of <1:10, since the ink runs.

FIG. 3 now shows schematically the construction of an aerosol jet printing device 9 according to the invention, with reference to which the method according to the invention can be explained in more detail. The atomiser 10 described here is heated and is supplied with the aerosol jet ink according to the invention. The atomiser gas which is supplied to the atomiser 10 is likewise heated to a temperature between 70 and 100° C. The produced aerosol is supplied to the likewise heated virtual impactor 11, the hoses and supply pipes or supply lines connecting the components likewise being heated to an operating temperature of approx. 60° C. The focusing or sheath gas supplied likewise to the heated printing head 12 need not be heated so that the focusing or sheath gas contributes to the cooling of the heated aerosol and the viscosity thereof is increased on the way to the substrate 13. As a significant difference from the state of the art, no heating of the substrate 13 is required here, so that the produced aerosol droplets solidify on the way to the substrate at the latest upon contact with the substrate surface and running is impossible. Because of the long-chain alcohols contained in the ink, it is likewise ensured that the aerosol droplets, upon solidifying, have good adhesion force against the further already adhering particles and hence a specific growth in height of the applied metallisation is ensured, however a significantly improved aspect ratio relative to the state of the art being able to be maintained.

FIG. 4 shows the results which can be achieved during the metallisation of solar cells with the method according to the invention. In comparison with

FIG. 2, the significantly improved aspect ratio can be detected. The metallisations achieved here, relative to those represented in FIG. 2, are very much higher and have an excellent aspect ratio so that a significantly improved current conduction and contact formation is possible.

1-28. (canceled)

29. A method for applying conductive structures on solar cells, in which a hot melt aerosol ink is atomised by means of an aerosol jet printing system and a conductive contact is applied on the substrate surface of the solar cell, wherein the aerosol jet printing system is heated at least partially, with the proviso that the hot melt aerosol ink used has a viscosity η≦1 Pas at a temperature of at least 40° C.

30. The method according to claim 29, wherein the hot melt aerosol ink used contains 50 to 90% by weight of conductive particles as solids which are dispersed in a thermoplastic compound.

31. The method according to claim 29, wherein the conductive particles used have a diameter d₉₀ of less than 500 nm.

32. The method according to claim 29, wherein the hot melt aerosol ink used, in addition to the conductive particles, contains further solids, preferably metal oxides and/or glass frits.

33. The method according to claim 29, wherein the hot melt aerosol ink used contains at least one thermoplastic compound, preferably one or more C₁₄ to C₂₀ alcohols and/or thermoplastic polymers.

34. The method according to claim 29, wherein the hot melt aerosol ink used contains:
a) 50 to 90% by weight of solids, comprising metal particles, metal oxides and/or glass frits,
b) 10 to 20% by weight of a C₁₄ to C₂₀ linear alcohol as thermoplastic compound,
c) 10 to 30% by weight of a solvent and
d) 0.01 to 1% by weight of additives
the sum of the individual formulation components a) to d) being 100% by weight.

35. The method according to claim 29, wherein the hot melt aerosol ink used has a viscosity η≧200 Pas at room temperature.

36. The method according to claim 29, wherein the aerosol jet printing system used comprises at least one atomiser, one concentrator (virtual impactor) and one printing head.

37. The method according to claim 36, wherein the atomiser is operated with an atomiser gas which is heated to 70 to 100° C.

38. The method according to claim 36, wherein the hot melt aerosol ink in the atomiser is kept at a temperature of 40 to 70° C.

39. The method according to claim 36, wherein the concentrator (virtual impactor), the printing head and also the transport hoses connecting the individual components are kept at a temperature of 50 to 100° C.

40. The method according to claim 29, wherein the aerosol jet printing system used is configured to be completely heatable.

41. The method according to claim 29, wherein front-side contacts are applied.

42. The method according to claim 29, Wherein the substrate surface is formed from coated or uncoated silicon or glass.

43. The method according to claim 29, wherein the deposited metal contacts have an aspect ratio (height to width) of 1:3 to 1:10.

44. The method according to claim 29, wherein the substrate surface of the solar cell is not heated or cooled.

45. The method according to claim 29, wherein after the aerosol jet printing process, a galvanic thickening or reinforcing of the applied conductive structures, preferably with silver and/or copper, is effected.

46. A hot melt aerosol ink for aerosol jet printing systems for metallising
substrate surfaces of solar cells, comprising:
a) 50 to 90% by weight of solids, comprising conductive particles, metal oxides and/or glass frits,
b) 10 to 20% by weight of a C₁₄ to C₂₀ linear alcohol as thermoplastic compound,
c) 10 to 30% by weight of a solvent and
d) 0.01 to 1% by weight of additives the sum of the individual formulation components a) to d) being 100% by weight and the viscosity at room temperature being >η=200 Pas.

47. The hot melt aerosol ink according to claim 46, wherein the viscosity η at room temperature is in the range of 200 to 5,000 Pas.

48. The hot melt aerosol ink according to claim 46, wherein the viscosity has been adjusted via the quantity and type of thermoplastic compound used.

49. The hot melt aerosol ink according to claim 46, wherein the diameter d₉₀ of the conductive particles is less than 500 nm.

50. The hot melt aerosol ink according to claim 46, wherein the conductive particles are metal particles, preferably metal particles selected from the group comprising Ag, Ni, Zn, Sn, Cr, Co, Ti, W and/or mixtures thereof.

51. The hot melt aerosol ink according to claim 46, wherein the metal oxides are selected from lead oxide, bismuth oxide, titanium oxide, aluminium oxide and/or mixtures thereof.

52. The hot melt aerosol ink according to claim 46, wherein the thermoplastic compound is selected from the group comprising C₁₄ to C₁₆ linear aliphatic alcohols and/or mixtures thereof.

53. The hot melt aerosol ink according to claim 46, wherein the solvent is selected from glycol ether, n-methylpyrrolidone, 2-(2-butoxyethoxy)ethanol and/or mixtures thereof.

54. The hot melt aerosol ink according to claim 46, wherein dispersants and/or defoamers are contained as additives.

55. An aerosol jet printing system comprising at least, one atomiser, one concentrator and one printing head and also connection hoses connecting these components, wherein at least one of the components, atomiser, concentrator, printing head and/or connection hoses, is configured to be heatable.

56. The aerosol jet printing system according to claim 55, wherein all the components are configured to be heatable.
